(19) United States
(12) Patent Application Publication
(10) Pub. No.: US 2014/0220754 A1
(43) Pub. Date: Aug. 7, 2014

(54) SEMICONDUCTOR DEVICE AND METHOD OF FORMING THE SAME

(71) Applicant: Samsung Electronics Co., Ltd., Suwon-Si (KR)

(72) Inventor: Chungki MIN, Pyeongtaek-si (KR)

(73) Assignee: Samsung Electronics Co., Ltd., Suwon-Si (KR)

(21) Appl. No.: 14/064,516

(22) Filed: Oct. 28, 2013

(30) Foreign Application Priority Data
Feb. 7, 2013 (KR) 10-2013-0014001

(51) Int. Cl. H01L 29/66

(52) U.S. Cl. CPC H01L 29/66477
USPC 438/287

(57) ABSTRACT

A method of forming a semiconductor device includes forming first sacrificial patterns on a substrate, the first sacrificial patterns spaced apart from each other, forming a capping layer on the first sacrificial patterns, forming a gap insulating layer spaced apart from a lower portion of the capping layer between the first sacrificial patterns in a vertical direction, planarizing the gap insulating layer and the capping layer to expose the first sacrificial patterns, removing the first sacrificial patterns to form trenches, and forming conductive patterns in the trenches, the conductive patterns having an air gap therebetween and between the lower portion of the capping layer and the gap insulating layer.

### CROSS-REFERENCE TO RELATED APPLICATIONS

This U.S. non-provisional patent application claims priority under 35 U.S.C. §119 to Korean Patent Application No. 10-2013-0014001, filed on Feb. 7, 2013, the entirety of which is incorporated by reference herein.

### BACKGROUND

1. Field

Example embodiments of the inventive concepts relate to a semiconductor and, more particularly, to a semiconductor device including an air gap disposed between conductive patterns and a method of forming the same.

2. Description of the Related Art

Pitches of metal interconnections of semiconductor devices have been reduced because of fineness, high-capacity, and high integration of the semiconductor devices. Thus, parasitic capacitances in the semiconductor devices may increase to reduce operating speeds of the semiconductor devices. To resolve the above problems, various research (e.g., a relatively low resistance copper interconnection and/or a low-k dielectric) has been conducted for reducing the parasitic capacitances of the semiconductor devices.

### SUMMARY

Example embodiments of the inventive concepts provide a semiconductor device with improved reliability and a method of forming the same.

Example embodiments of the inventive concepts also provide a relatively high speed semiconductor device having a relatively low parasitic capacitance and method of forming the same.

According to example embodiments, a method of forming a semiconductor device may include forming first sacrificial patterns spaced apart from each other on a substrate, forming a capping layer on the first sacrificial patterns, forming a gap insulating layer spaced apart from a lower portion of the capping layer between the first sacrificial patterns in a vertical direction, planarizing the gap insulating layer and the capping layer to expose the first sacrificial patterns, removing the first sacrificial patterns to form trenches, and forming conductive patterns in the trenches, the conductive patterns having an air gap therebetween and between the lower portion of the capping layer and the gap insulating layer.

In example embodiments, the method may further include forming a second sacrificial pattern on the capping layer between the first sacrificial patterns, and forming a porous layer on the capping layer and the second sacrificial pattern.

In example embodiments, the air gap may be formed by removing the second sacrificial pattern through the porous layer.

In example embodiments, a top surface of the second sacrificial pattern may be closer to the substrate than top surfaces of the first sacrificial patterns.

In example embodiments, a groove may be defined between the first sacrificial patterns, and the gap insulating layer may be formed on an upper region of the groove such that the air gap is in a lower region of the groove.

In example embodiments, the method may further include forming an interlayer insulating layer on the substrate, and the first sacrificial patterns may be formed on the interlayer insulating layer. The first sacrificial patterns may be formed by etching the interlayer insulating layer to form a recess region in the interlayer insulating layer, and the recess region may be disposed under a space between the first sacrificial patterns.

In example embodiments, the interlayer insulating layer may include contacts connected to the conductive patterns, and the air gap may extend into the recess region between the contacts.

In example embodiments, the conductive patterns may include one of a metal and a doped semiconductor.

In example embodiments, the method may further include forming a source/drain region in the substrate exposed by the first sacrificial patterns, and forming a gate insulating layer on the substrate.

In example embodiments, the conductive patterns may include one of tungsten and aluminum.

In example embodiments, the gate insulating layer may include at least one of silicon oxide, a nitride, an oxynitride, a metal silicate, and an insulating metal oxide.

According to example embodiments, a semiconductor device may include an interlayer insulating layer having a recess region on a substrate, and conductive patterns on the interlayer insulating layer, the conductive patterns being spaced apart from each other and including an air gap therebetween extending into the recess region, the recess region being disposed under a space between the conductive patterns, wherein a bottom surface of the recess region may be closer to the substrate than a bottom surface of the conductive region.

In example embodiments, the semiconductor device may further include a capping layer including a first portion between the air gap and the conductive patterns and a second portion between the air gap and interlayer insulating layer, and a gap insulating layer on the air gap between the conductive patterns, the gap insulating layer spaced apart from the interlayer insulating layer.

In example embodiments, the semiconductor device may further include a porous layer including a first portion between the gap insulating layer and the air gap and a second portion between the gap insulating layer and the capping layer.

In example embodiments, a bottom surface of the air gap may be closer to the substrate than bottom surfaces of the conductive patterns, and a top surface of the air gap may be closer to the substrate than top surfaces of the conductive patterns.

According to example embodiments, a method of forming a semiconductor device may include forming first sacrificial patterns on a substrate, forming a capping layer on the first sacrificial patterns, forming a second sacrificial pattern on the capping layer between the first sacrificial patterns, forming a porous layer on the capping layer and the second sacrificial pattern, removing the first sacrificial patterns to form trenches, forming conductive patterns in the trenches and removing the second sacrificial pattern through the porous layer to form an air gap between the conductive patterns.

In example embodiments, the second sacrificial pattern may have a top surface closer to the substrate than top surfaces of the first sacrificial patterns.

In example embodiments, the method may further include forming an interlayer insulating layer on the substrate, and the first sacrificial patterns may be formed on the interlayer insulating layer.

In example embodiments, the first sacrificial patterns may be formed by etching the interlayer insulating layer to form a recess region in the interlayer insulating layer, the recess region being disposed under a space between the first sacrificial patterns.

In example embodiments, the interlayer insulating layer may form contacts connected to the conductive patterns, and the air gap may extend into the recess region between the contacts.

In example embodiments, the conductive patterns may be formed of one of a metal and a doped semiconductor.

In example embodiments, the method may further include forming a source/drain region in the substrate exposed by the first sacrificial patterns, and forming a gate insulating layer on the substrate.

In example embodiments, the gate insulating layer may be formed of at least one of silicon oxide, a nitride, an oxynitride, a metal silicate, and an insulating metal

### BRIEF DESCRIPTION OF THE DRAWINGS

Example embodiments of the inventive concepts will become more apparent in view of the attached drawings and accompanying detailed description.

FIG. 1 is a cross-sectional view illustrating a semiconductor device according to example embodiments of the inventive concepts;

FIG. 2 is a cross-sectional view illustrating a semiconductor device according to example embodiments of the inventive concepts;

FIG. 3 is a cross-sectional view illustrating a semiconductor device according to example embodiments of the inventive concepts;

FIG. 4 is a cross-sectional view illustrating a semiconductor device according to example embodiments of the inventive concepts;

FIG. 5 is a cross-sectional view illustrating a semiconductor device according to example embodiments of the inventive concepts;

FIGS. 6 to 12 are cross-sectional views illustrating a method of forming a semiconductor device according to example embodiments of the inventive concepts;

FIG. 13 is a cross-sectional view illustrating a method of forming a semiconductor device according to example embodiments of the inventive concepts;

FIGS. 14 and 15 are cross-sectional views illustrating a method of forming a semiconductor device according to example embodiments of the inventive concepts;

FIG. 16 is a cross-sectional view illustrating a method of forming a semiconductor device according to example embodiments of the inventive concepts;

FIGS. 17 to 21 are cross-sectional views illustrating a method of forming a semiconductor device according to example embodiments of the inventive concepts;

FIG. 22 illustrates an example of package modules including semiconductor devices according to various example embodiments of the inventive concepts;

FIG. 23 is a schematic block diagram illustrating an example of electronic devices including semiconductor devices according to various example embodiments of the inventive concepts; and

FIG. 24 is a schematic block diagram illustrating an example of memory systems including semiconductor devices according to various example embodiments of the inventive concepts.

### DETAILED DESCRIPTION

The inventive concepts will now be described more fully hereinafter with reference to the accompanying drawings, in which example embodiments of the inventive concepts are shown. The advantages and features of the inventive concepts and methods of achieving them will be apparent from the following example embodiments that will be described in more detail with reference to the accompanying drawings. It should be noted, however, that the inventive concepts are not limited to the following example embodiments, and may be implemented in various forms. Accordingly, the example embodiments are provided only to disclose the inventive concepts and let those skilled in the art know the category of the inventive concepts. In the drawings, example embodiments of the inventive concepts are not limited to the specific examples provided herein and are exaggerated for clarity.

The terminology used herein is for the purpose of describing particular embodiments only and is not intended to limit the inventive concepts. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, example embodiments in the detailed description will be described with sectional views as ideal example views of the inventive concepts. Accordingly, shapes of the example views may be modified according to manufacturing techniques and/or allowable errors. Therefore, example embodiments of the inventive concepts are not limited to the specific shape illustrated in the example views, but may include other shapes that may be created according to manufacturing processes. Areas illustrated in the drawings have general properties, and are used to illustrate specific shapes of elements. Thus, this should not be construed as limited to the scope of the inventive concepts.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present inventive concepts. Example embodiments of aspects of the present inventive concepts explained and illustrated herein include their complementary counterparts. The same reference numerals or the same reference designators denote the same elements throughout the specification.

Moreover, example embodiments are described herein with reference to cross-sectional illustrations and/or plane illustrations that are idealized example illustrations. Accordingly, variations from the shapes of the illustrations as a result, for example, of manufacturing techniques and/or tolerances, are to be expected. Thus, example embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

Semiconductor devices according to example embodiments of the inventive concepts will be described with reference to the drawings hereinafter.

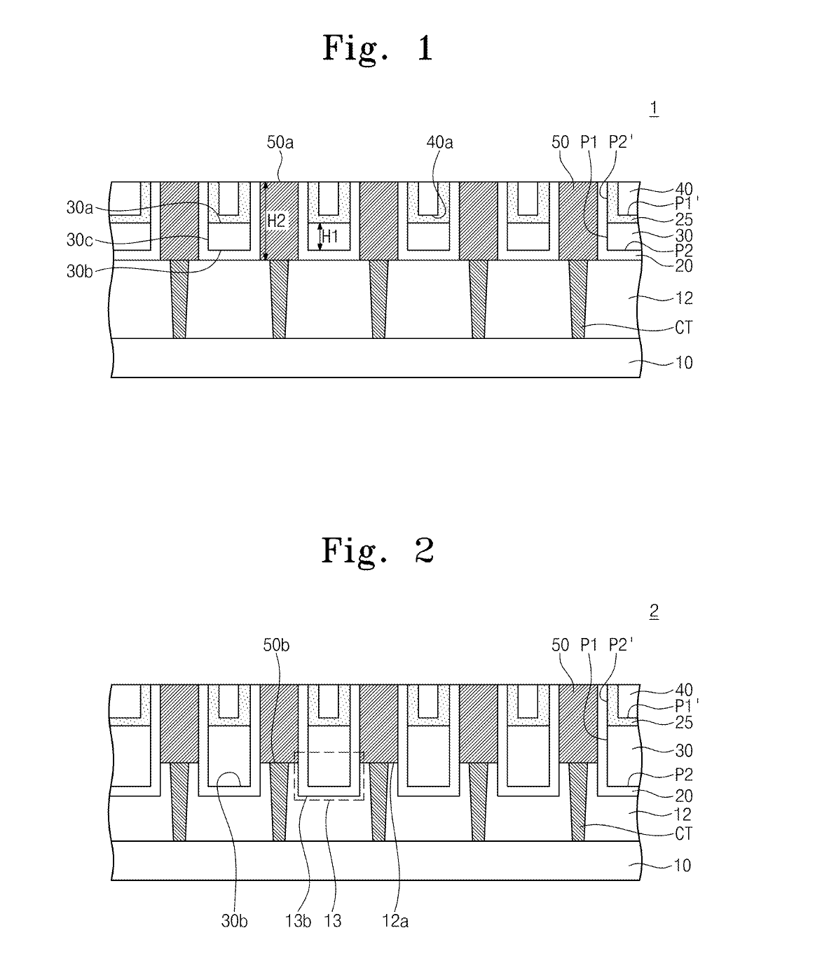

FIG. 1 is a cross-sectional view illustrating a semiconductor device according to example embodiments of the inventive concepts.

Referring to FIG. 1, a semiconductor device 1 may include an interlayer insulating layer 12, a capping layer 20, a porous layer 25, an air gap 30, a gap-insulating layer 40 and conductive patterns 50 that are disposed on a substrate 10.

The substrate 10 may be a semiconductor substrate. Semiconductor discrete elements (not shown) and/or conductive regions (not shown) may be provided on/in the substrate 100.

The interlayer insulating layer 12 may have contacts CT connected to the semiconductor discrete elements (not shown) and/or the conductive regions (not shown). The contacts CT may include a non-insulating material, for example, a conductive material, a metal (e.g., tungsten), or a doped semiconductor.

The conductive patterns 50 may be spaced apart from each other on the interlayer insulating layer 12. The conductive patterns 50 may extend in parallel to each other in one direction. The one direction may be parallel to a top surface of the substrate 10. The conductive patterns 50 may be electrically connected to the contacts CT. The conductive patterns 50 may include a metal (e.g., copper (Cu)) or a doped semiconductor.

A first portion P1 of the capping layer 20 may contact sidewalls of the conductive patterns 50 and a second portion P2 of the capping layer 20 may extend onto the interlayer insulating layer 12 between the conductive patterns 50. The capping layer 20 may include silicon oxide or silicon nitride.

The porous layer 25 may be provided on the capping layer 20. A first portion P1′ of the porous layer 25 may be vertically spaced apart from a lower portion of the capping layer 20 and a second portion P2′ of the porous layer 25 may be in contact with an upper portion of the capping layer 20. The porous layer 25 may be a dielectric (or, low-k) layer. The porous layer 25 may include silicon oxide, for example, a silicon oxide containing carbon.

The air gap 30 may be disposed between the conductive patterns 50 on the interlayer insulating layer 12. The air gap 30 may include a top surface 30a, a bottom surface 30b facing the top surface 30a, and a sidewall 30c connected between the top and bottom surfaces 30a and 30b. The bottom surface 30b and the sidewall 30c of the air gap 30 may be in contact with the capping layer 20, and the top surface 30a of the air gap 30 may be in contact with the porous layer 25. The top surface 30a of the air gap 30 may be lower than top surfaces 50a of the conductive patterns 50. The air gap 30 may include air, and the air may have a dielectric constant (e.g., about 1.0006) lower than dielectric constants of a carbon material and silicon oxide. Thus, a parasitic capacitance between the conductive patterns 50 may be reduced by the air gap 30. A height H1 of the air gap 30 may be less than a height H2 of the conductive patterns 50. As the height H1 of the air gap 30 increases, the parasitic capacitance between the conductive patterns 50 may be further reduced.

The gap insulating layer 40 may be provided on the porous layer 25. The gap insulating layer 40 may be vertically spaced apart from a lower portion of the capping layer 20 disposed on the interlayer insulating layer 12 between the conductive patterns 50. A bottom surface 40a of the gap insulating layer 40 may not be in contact with the interlayer insulating layer 12 and/or the capping layer 20. The gap insulating layer 40 may include a dielectric oxide, for example, a plasma-enhanced tetra ethyl ortho silicate (PE-TEOS). The gap insulating layer 40 may be disposed between the conductive patterns 50 and may prevent or inhibit a short of the conductive patterns 50.

The semiconductor device 1 of example embodiments includes the air gap 30 between the conductive patterns 50. Thus, the parasitic capacitance of the semiconductor device 1 may be reduced and an operating speed of the semiconductor device 1 may increase.

FIG. 2 is a cross-sectional view illustrating a semiconductor device according to example embodiments of the inventive concepts. In example embodiments, the descriptions to the same elements as described in FIG. 1 will be omitted or mentioned briefly for the purpose of ease and convenience in explanation.

Referring to FIG. 2, a semiconductor device 2 may include an interlayer insulating layer 12, a capping layer 20, a porous layer 25, an air gap 30, a gap insulating layer 40 and conductive patterns 50 that are disposed on a substrate 10.

The interlayer insulating layer 12 may include a recess region 13. A bottom surface 13b of the recess region 13 may be closer to the substrate than a top surface 12a of the interlayer insulating layer 12. The recess region 13 may be provided in the interlayer insulating layer 12 under a space between the conductive patterns 50. Because the interlayer insulating layer 12 has the recess region 13, the air gap 30 may extend into the recess region 13. For example, a bottom surface 30b of the air gap 30 may be closer to the substrate than a bottom surface 50b of the conductive pattern 50. The air gap 30 may be disposed between the conductive patterns 50. Additionally, the air gap 30 may extend downward between the contacts CT disposed in the interlayer insulating layer 12. Thus, the parasitic capacitance between the conductive patterns 50 and a parasitic capacitance between the contacts CT may be reduced.

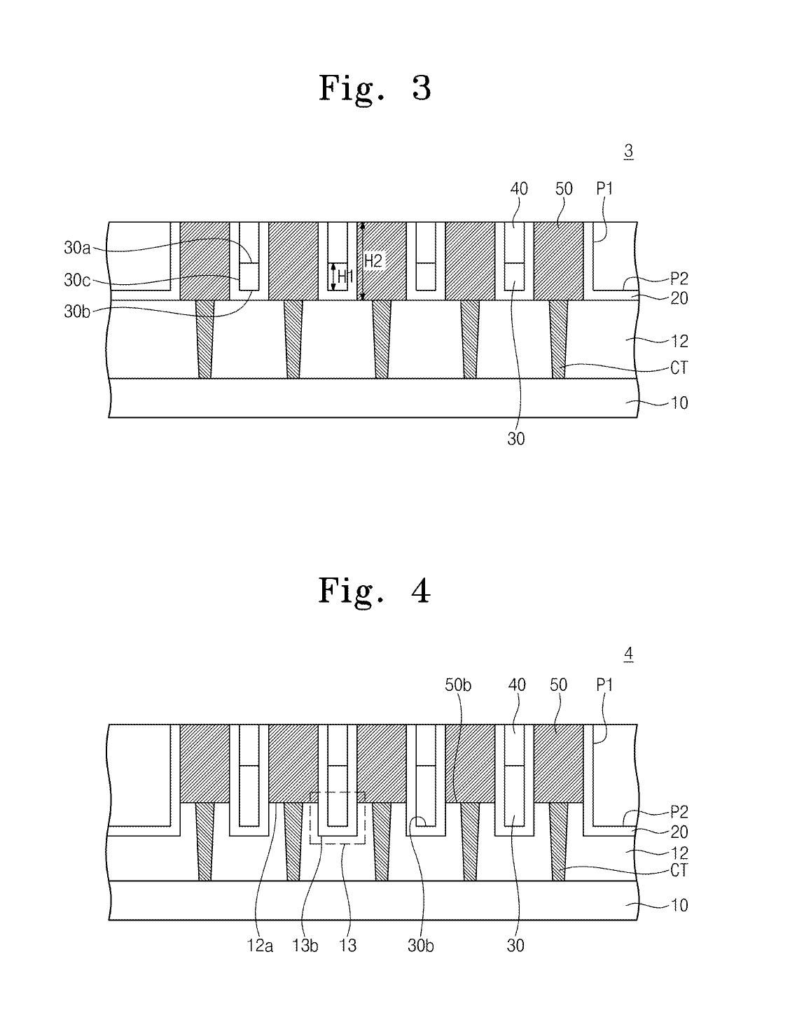

FIG. 3 is a cross-sectional view illustrating a semiconductor device according to example embodiments of the inventive concepts. In example embodiments, the descriptions to the same elements as described above will be omitted or mentioned briefly for the purpose of ease and convenience in explanation.

Referring to FIG. 3, a semiconductor device 3 may include an interlayer insulating layer 12, a capping layer 20, an air gap 30, a gap insulating layer 40 and conductive patterns 50 that are disposed on a substrate 10. The semiconductor device 3 according to example embodiments may not include the aforementioned porous layer 25 of FIG. 1.

The air gap 30 may be provided between the conductive patterns 50. The air gap 30 may have a bottom surface 30b and a sidewall 30c that are in contact with the capping layer 20. Unlike FIG. 1, a top surface 30a of the air gap 30 may be in contact with the gap insulating layer 40. A height H1 of the air gap 30 may be less than a height H2 of the conductive patterns 50. The top surface 30a of the air gap 30 may be lower than a top surface of the conductive pattern 50. The gap insulating layer 40 may be disposed on the air gap 30. The gap insulating layer 40 may be spaced apart from a lower portion of the capping layer 20 but may be in contact with an upper portion of the capping layer 20.

FIG. 4 is a cross-sectional view illustrating a semiconductor device according to example embodiments of the inventive concepts. In example embodiments, the descriptions to the same elements as described above will be omitted or mentioned briefly for the purpose of ease and convenience in explanation.

Referring to FIG. 4, a semiconductor device 4 may include an interlayer insulating layer 12, a capping layer 20, an air gap 30, a gap insulating layer 40 and conductive patterns 50 that are disposed on a substrate 10.

The interlayer insulating layer 12 may include a recess region 13. A bottom surface 13b of the recess region 13 may be closer to the substrate than a top surface 12a of the interlayer insulating layer 12. The recess region 13 may be provided in the interlayer insulating layer 12 under a space between the conductive patterns 50. Because the interlayer insulating layer 12 has the recess region 13, the air gap 30 may extend into the recess region 13. For example, a bottom surface 30b of the air gap 30 may be closer to the substrate than a bottom surface 50b of the conductive pattern 50. The air gap 30 may be disposed between the conductive patterns 50 and may extend downward between the contacts CT.

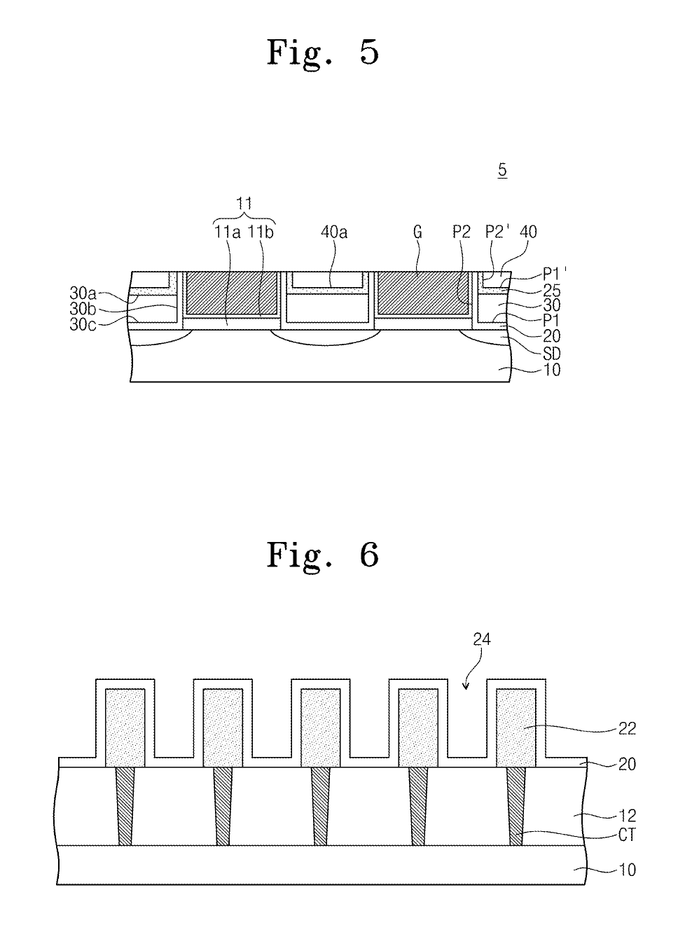

FIG. 5 is a cross-sectional view illustrating a semiconductor device according to example embodiments of the inventive concepts. In example embodiments, the descriptions to the same elements as described above will be omitted or mentioned briefly for the purpose of ease and convenience in explanation.

Referring to FIG. 5, a semiconductor device 5 may include a gate insulating layer 11, an air gap 30, a capping layer 20, a porous layer 25, a gap insulating layer 40 and gate electrodes G that are disposed on a substrate 10.

The substrate 10 may have source/drain regions SD. The source/drain regions SD may be spaced apart from each other in the substrate 10. The substrate 10 may include silicon, and the source/drain regions SD may include dopants.

The gate insulating layer 11 may be provided on the substrate 10. The gate insulating layer 11 may include a first gate insulating layer 11a and a second gate insulating layer 11b. The first gate insulating layer 11a may be disposed between the substrate 10 and the gate electrodes G. In example embodiments, the first gate insulating layer 11a may include silicon oxide. In other embodiments, the first gate insulating layer 11a may include a tunnel insulating layer, a charge storage layer, and a blocking insulating layer which are sequentially stacked. In this case, the second gate insulating layer 11b may be omitted.

The second gate insulating layer 11b may be disposed on sidewalls of the gate electrodes G and the first insulating layer 11a. The second gate insulating layer 11b may include at least one of a nitride (e.g., silicon nitride), an oxynitride (e.g., silicon oxynitride), a metal silicate, and a relatively high melting point insulating metal oxide having a relatively high dielectric constant, for example, hafnium oxide and/or aluminum oxide.

The gate electrodes G may cover the gate insulating layer 11 and may be disposed on the substrate 10. Each of the gate electrodes G may be disposed on the substrate 10 between the source/drain regions SD. The gate electrodes G may be spaced apart from the source/drain regions SD. That is, the gate electrodes G may not be in contact with the source/drain regions SD. The gate electrodes G may include a semiconductor oxide (e.g., indium-tin oxide (ITO) or indium-zinc oxide (IZO)) or a metal (e.g., copper (Cu), titanium (Ti), molybdenum (Mo), or aluminum (Al)). The air gap 30 may be provided between the gate electrodes 30. Thus, a parasitic capacitance between the gate electrodes G may be lower than a parasitic capacitance between gate electrodes having a carbon material or silicon oxide therebetween. That is, the parasitic capacitance between the gate electrodes G may be reduced by the air gap 30.

The capping layer 20 may be provided on sidewalls of the gate electrodes G and may extend onto the substrate 10 between the gate electrodes G. The capping layer 20 may include silicon oxide or silicon nitride.

The porous layer 25 may be provided on the capping layer 20. The porous layer 25 may be vertically spaced apart from a lower portion of the capping layer 20 that is disposed on the substrate 10 between the gate electrodes G. The porous layer 25 may be in contact with an upper portion of the capping layer 20. The porous layer 25 may include silicon oxide, for example, a silicon oxide containing carbon.

The air gap 30 may be provided on the capping layer 20. In example embodiments, the air gap 30 may be disposed between the gate electrodes G. The air gap 30 may have a top surface 30a, a bottom surface 30b opposite to the top surface 30a, and a sidewall 30c connected between the top and bottom surfaces 30a and 30b. The bottom surface 30b and the sidewall 30c of the air gap 30 may be in contact with the capping layer 20 and/or the gap insulating layer 40. The top surface 30a of the air gap 30 may be in contact with the porous layer 25. The top surface 30a of the air gap 30 may be lower than top surfaces of the gate electrodes G.

The gap insulating layer 40 may be provided on the substrate 10. Because the air gap 30 is provided, a bottom surface 40a of the gap insulating layer 40 is not in contact with the substrate 10 and/or the capping layer 20. That is, the bottom surface 40a of the gap insulating layer 40 is spaced apart from the substrate 10 and/or the capping layer 20. The gap insulating layer 40 may include a dielectric oxide, e.g., PE-TEOS.

Hereinafter, methods of forming a semiconductor device will be described with reference to the drawings.

FIGS. 6 to 12 are cross-sectional views illustrating a method of forming a semiconductor device according to example embodiments of the inventive concepts. Hereinafter, the same descriptions as described with reference to FIG. 1 will be omitted or mentioned briefly for the purpose of ease and convenience in explanation.

Referring to FIG. 6, an interlayer insulating layer 12 may be formed on a substrate 10. Contacts CT may be formed in the interlayer insulating layer 12. The contacts CT may include a metal material (e.g., tungsten).

First sacrificial patterns 22 may be formed on the interlayer insulating layer 12. The first sacrificial patterns 22 may extend parallel to each other along one direction parallel to a top surface of the substrate 10. The first sacrificial patterns 22 may be spaced apart from each other to correspond to the contacts CT, respectively. A groove 24 may be defined between the first sacrificial patterns 22 adjacent to each other. As illustrated in FIG. 6, a plurality of the grooves 24 may be formed, and the grooves 24 and the first sacrificial patterns 22 may be alternately arranged. In example embodiments, the first sacrificial patterns 22 may be formed of a spin-on-hardmask (SOH) material. For example, the first sacrificial patterns 22 may be formed of a hydrocarbon-based insulating material. In other embodiments, the first sacrificial patterns 22 may include an organic material, a photoresist, or amorphous silicon.

A capping layer 20 may be formed to cover the interlayer insulating layer 12 and the first sacrificial patterns 22. The capping layer 20 may include silicon oxide or silicon nitride.

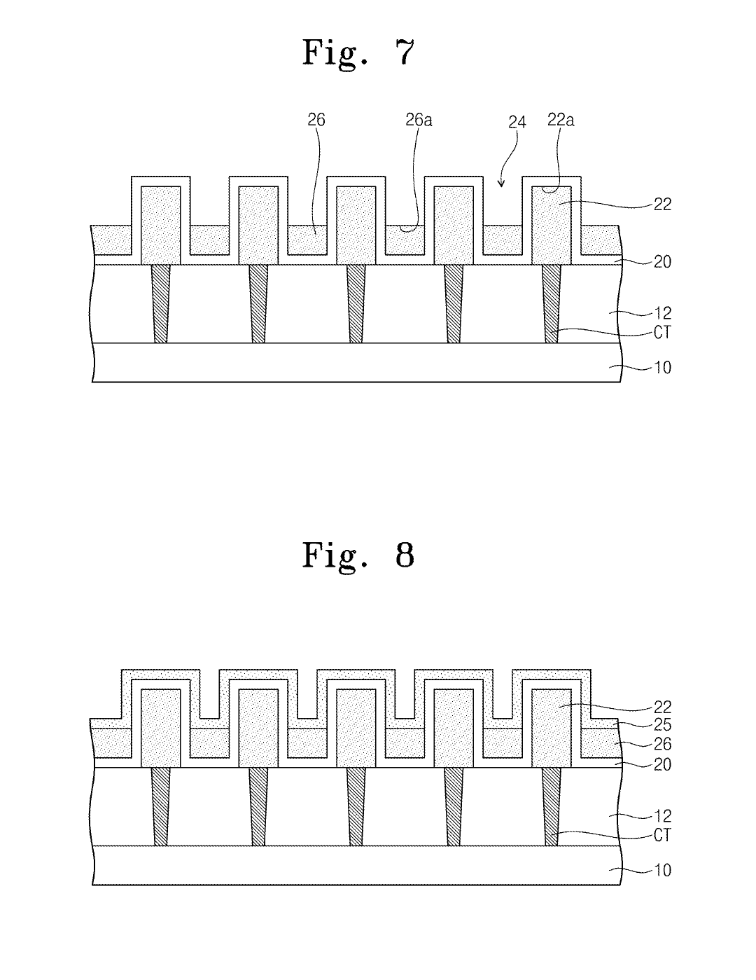

Referring to FIG. 7, second sacrificial patterns 26 may be formed on the interlayer insulating layer 12, so as to cover the capping layer 20. The second sacrificial patterns 26 may be disposed in the grooves 24, respectively. The second sacrificial patterns 26 may be formed by depositing the same material as or a similar material to the first sacrificial patterns 22. The second sacrificial patterns 26 may be separated from the first sacrificial patterns 22 by the capping layer 20. Upper portions of the second sacrificial patterns 26 may be etched by an etch-back process so that top surfaces 26a of the second sacrificial patterns 26 may be lower than top surfaces 22a of the first sacrificial patterns 22. In example embodiments, the etch-back process of the second sacrificial patterns 26 may be a dry etch-back process. Additionally, a sacrificial layer for the second sacrificial patterns 26 which is disposed on the second sacrificial patterns 26 may be removed by the etch-back process, so that an upper portion of the capping layer 20 may be exposed. The second sacrificial patterns 26 may be spaced apart from each other with the first sacrificial patterns 22 therebetween. That is, the first sacrificial patterns 22 and the second sacrificial patterns 26 may be alternately arranged.

Referring to FIG. 8, a porous layer 25 may be formed on the interlayer insulating layer 12 to cover the capping layer 20 and the second sacrificial patterns 26. The porous layer 25 may be in contact with the upper portion of the capping layer 20 but may be vertically spaced apart from lower portions of the capping layer 20 that are disposed between the first sacrificial patterns 22. A silicon oxide layer containing carbon may be formed and then may be thermally treated to form the porous layer 25. The porous layer 25 may be formed using an atomic layer deposition (ALD) process. The porous layer 25 may correspond to a porous low-k dielectric layer, e.g., a SiCOH layer. A precursor for the porous layer 25 may include trimethylsilane (3MS, (CH₃)₃—Si—H), tetramethylsilane (4MS, (CH₃)₄—Si), and/or vinyltrimethylsilane (VTMS, CH₂=CH—Si(CH₃)₃).

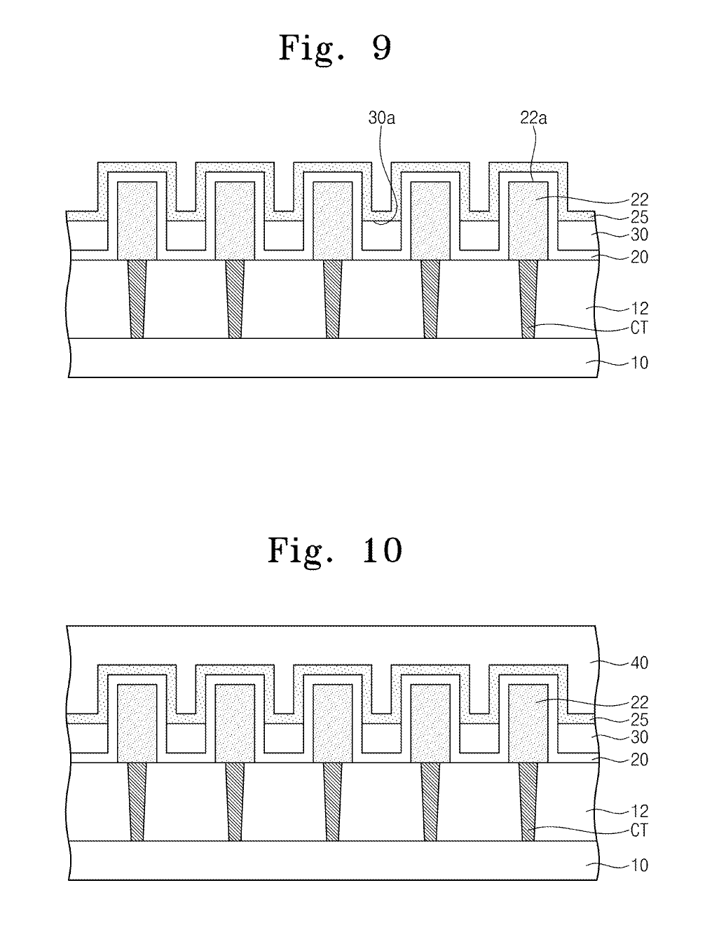

Referring to FIG. 9, the second sacrificial patterns 26 may be removed to form air gaps 30. The removal of the second sacrificial patterns 26 may be performed by an ashing process. Thus, an insulating layer is not disposed between the air gaps 30 and conductive patterns 50 formed later (see FIG. 1) so that a parasitic capacitance between the conductive patterns 50 can be reduced.

For example, an organic material in the second sacrificial patterns 26 may be removed through the porous layer 25. The air gap 30 may be formed to have a height lower than a height of the first sacrificial pattern 22. Top surfaces 30a of the air gaps 30 may be lower than the top surfaces 22a of the first sacrificial patterns 22. Referring to FIG. 10, a gap insulating layer 40 may be formed on the porous layer 25 to cover the porous layer 25. The gap insulating layer 40 may be formed to be spaced apart from the lower portions of the capping layer 20. For example, the gap insulating layer 40 may be formed by depositing a dielectric oxide (e.g., PE-TEOS).

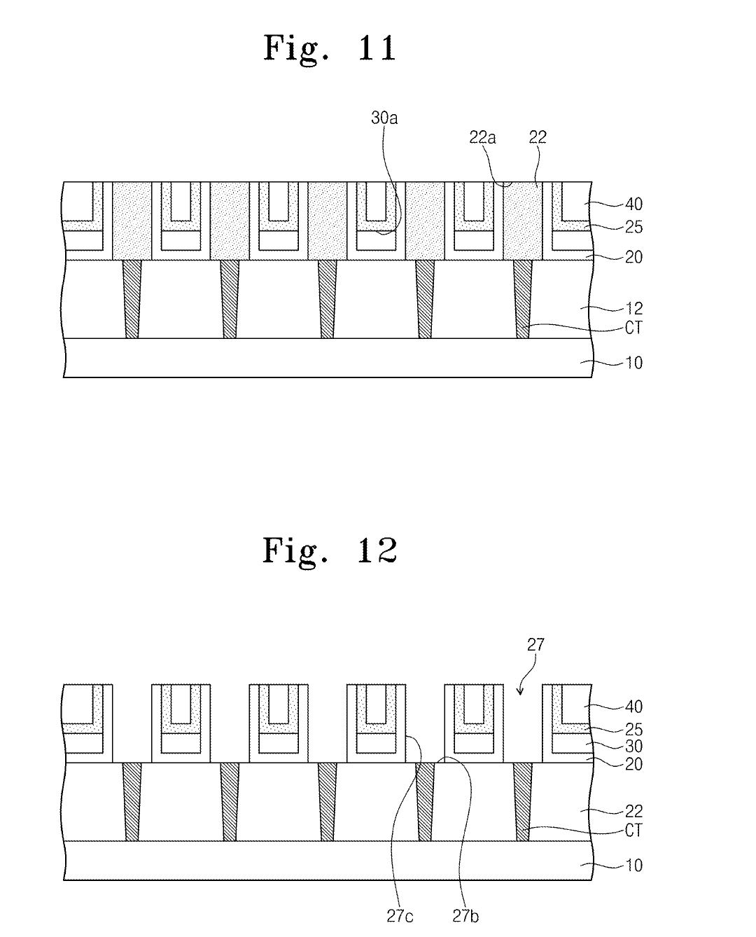

Referring to FIG. 11, the gap insulating layer 40 may be planarized. At this time, the capping layer 20 and the porous layer 25 on the top surfaces of the first sacrificial patterns 22 may also be planarized to expose the top surfaces 22a of the first sacrificial patterns 22. The gap insulating layer 40, the capping layer 20, and/or the porous layer 25 may be planarized by a chemical mechanical polishing (CMP) process. The planarization process may have an etch selectivity with respect to the first sacrificial patterns 22. Thus, the first sacrificial patterns 22 may be used a polishing stop layer in the planarization process. If the top surface 30a of the air gap 30 is disposed at the same level as the top surface of the first sacrificial pattern 22, the air gap 30 may be damaged in the planarization process. However, according to example embodiments of the inventive concepts, the top surface 30a of the air gap 30 is lower than the top surface of the first sacrificial pattern 22. Thus, it is possible to prevent or inhibit the air gap 30 from being damaged in the planarization process.

Referring to FIG. 12, the first sacrificial patterns 22 may be removed to form trenches 27. The first sacrificial patterns 22 may be removed by an ashing process, for example, a dry ashing process. The trench 27 may have a bottom surface 27b exposing the contact CT and a sidewall 27c exposing the capping layer 20.

Referring again to FIG. 1, conductive patterns 50 may be formed in the trenches 27 of FIG. 12, respectively. The conductive patterns 50 may be in contact with the contacts CT and/or the capping layer 20. Before the conductive patterns 50 are formed, a barrier layer (not shown) may be further formed in the trenches 27 of FIG. 12. The barrier layer may include tantalum (Ta) and/or tantalum nitride (TaN). The conductive patterns 50 may include a metal or a doped semiconductor. In example embodiments, a copper (Cu) seed may be formed in the trenches 27 of FIG. 12 and the trenches 27 may be filled with copper (Cu) by an electro plating (EP) method. The copper (Cu) may be planarized to remove the copper outside the trenches 27 of FIG. 12, thereby forming the conductive patterns 50. For example, the copper (Cu) may be planarized by a CMP process. The conductive patterns 50 may be separated from each other by the planarization process.

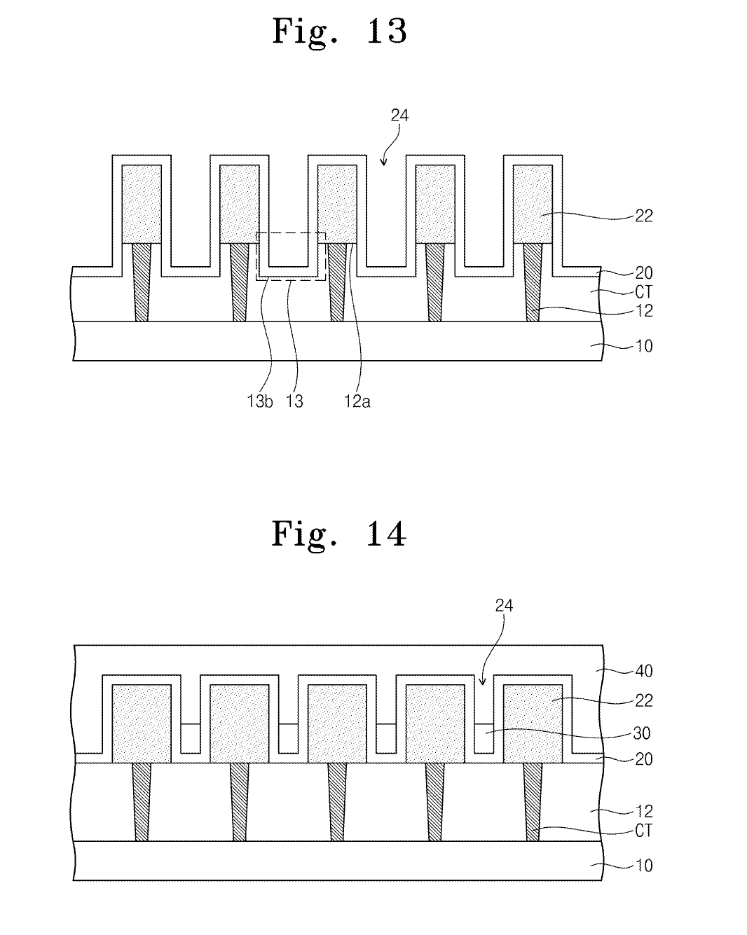

FIG. 13 is a cross-sectional view illustrating a method of forming a semiconductor device according to example embodiments of the inventive concepts. In example embodiments, the same descriptions as described above will be omitted or mentioned briefly for the purpose of ease and convenience in explanation.

Referring to FIG. 13, the interlayer insulating layer 12 may be provided on the substrate 10 and then the contacts CT may be formed in the interlayer insulating layer 12. The first sacrificial patterns 22 may be formed on the interlayer insulating layer 12. When the first sacrificial patterns 22 are formed, the interlayer insulating layer 12 may also be etched to form recess regions 13 in the interlayer insulating layer 12. The recess regions 13 may be formed in the interlayer insulating layer 12 under the grooves 24. Bottom surfaces 13b of the recess regions 13 may be closer to the substrate than the top surface 12a of the interlayer insulating layer 12 and bottom surfaces of the first sacrificial patterns 22. The capping layer 20 may be formed to conformally cover the first sacrificial patterns 22 and the recess regions 13.

Referring again to FIG. 2, the second sacrificial patterns (see 26 of FIG. 7) may be formed through the processes described with reference to FIGS. 6 and 7. At this time, the second sacrificial patterns may be formed to extend into the recess regions 13 of the interlayer insulating layer 12. Thus, the air gaps 30 may extend into the recess regions 13, respectively. Thereafter, the same subsequent processes as described in example embodiments may be performed to form the semiconductor device 2 illustrated in FIG. 2.

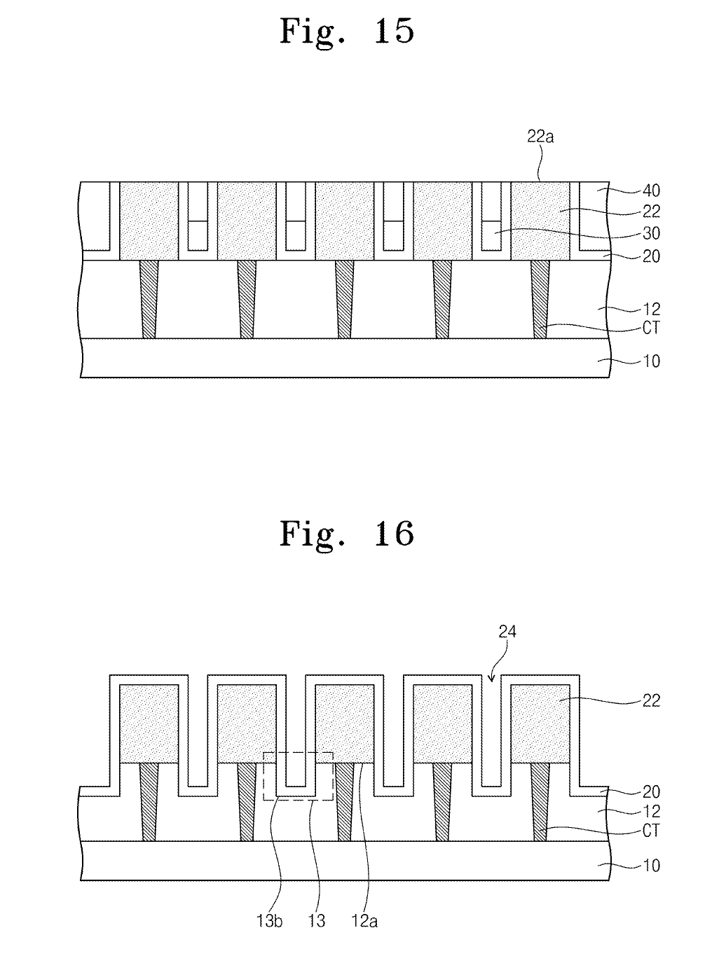

FIGS. 14 and 15 are cross-sectional views illustrating a method of forming a semiconductor device according to example embodiments of the inventive concepts. In example embodiments, the same descriptions as described above will be omitted or mentioned briefly for the purpose of ease and convenience in explanation.

Referring to FIG. 14, first sacrificial patterns 22 and a capping layer 20 may be sequentially formed on the interlayer insulating layer 12 described with reference to FIG. 6. A spacer between the first sacrificial patterns 22 in FIG. 14 may be narrower than a space between the first sacrificial patterns 22 of FIG. 6. A gap insulating layer 40 may be formed on the capping layer 20 to form air gaps 30. In example embodiments, the gap insulating layer 40 may be formed of a dielectric oxide having an undesirable step coverage property. Thus, the gap insulating layer 40 may be vertically spaced apart from the capping layer 20 disposed on the interlayer insulating layer 12 between the first sacrificial patterns 22. The gap insulating layer 40 may fill only upper regions of grooves 24 provided between the first sacrificial patterns 22. The gap insulating layer 40 may close the upper regions of the grooves 24, so that the air gaps 30 which are not filled with the gap insulating layer 40 may be formed in lower regions of the grooves 24.

Referring to FIG. 15, the gap insulating layer 40 and the capping layer 20 may be planarized to expose top surfaces 22a of the first sacrificial patterns 22. The planarization process may be performed by a CMP process and may have an etch selectivity with respect to the first sacrificial patterns 22. Thus, the first sacrificial patterns 22 may function as a polishing stop layer.

Referring again to FIG. 3, thereafter, the same subsequent processes as described in example embodiments may be performed to form the semiconductor device 3 of FIG. 3 according to example embodiments.

FIG. 16 is a cross-sectional view illustrating a method of forming a semiconductor device according to example embodiments of the inventive concepts. In example embodiments, the same descriptions as described above will be omitted or mentioned briefly for the purpose of ease and convenience in explanation.

Referring to FIG. 16, the sacrificial patterns 22 may be formed on the interlayer insulating layer 12. A space between the first sacrificial patterns 22 in FIG. 16 may be narrower than a space between the first sacrificial patterns 22 in FIG. 13. When the first sacrificial patterns 22 are formed, the interlayer insulating layer 12 may also be etched to form recess regions 13 in the interlayer insulating layer 12. The recess regions 13 may be formed under grooves 24 provided between the first sacrificial patterns 22. Bottom surfaces 13b of the recess regions 13 may be lower than the top surface 12a of the interlayer insulating layer 12 and the bottom surfaces of the first sacrificial patterns 22. The capping layer 20 may be formed to conformally cover the first sacrificial patterns 22 and the recess regions 13.

Referring again to FIG. 4, a gap insulating layer 40 having undesirable step coverage property may be formed on the capping layer 20. The gap insulating layer 40 may be formed of a dielectric oxide having the undesirable step coverage property. At this time, the gap insulating layer 40 may fill only upper regions of the grooves 24 of FIG. 16 provided between the first sacrificial patterns 22 of FIG. 16. Thus, the air gaps 30 that are not filled with the gap insulating layer 140 may be formed in lower regions of the grooves 24 of FIG. 16. Thereafter, the same subsequent processes as described in the first and third embodiments may be performed to form the semiconductor device 4 according to example embodiments of the inventive concepts.

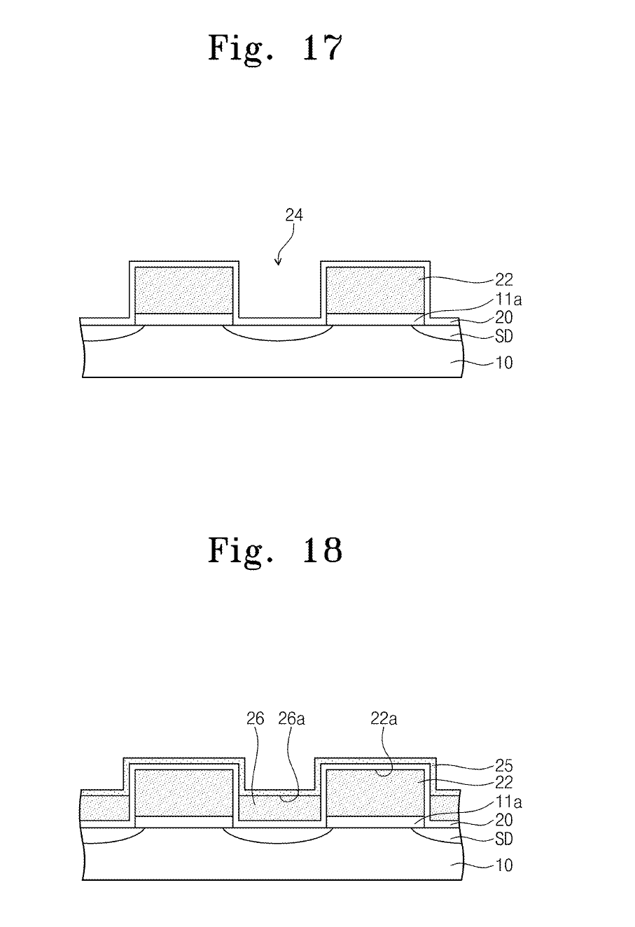

FIGS. 17 to 21 are cross-sectional views illustrating a method of forming a semiconductor device according to example embodiments of the inventive concepts. In example embodiments, the same descriptions as described above will be omitted or mentioned briefly for the purpose of ease and convenience in explanation.

Referring to FIG. 17, a substrate 10 having source/drain regions SD may be provided. A first gate insulating layer 11a may be formed on the substrate 10. In example embodiments, the first gate insulating layer 11a may be a silicon oxide layer. In other embodiments, the first gate insulating layer 11a may include a tunnel insulating layer, a charge storage layer, and a blocking insulating layer that are sequentially stacked on the substrate 10. First sacrificial patterns 22 may be formed on the first gate insulating layer 11a. In example embodiments, the first sacrificial patterns 22 may be formed of a SOH material or a hydrocarbon-based insulating material. In other embodiments, the first sacrificial patterns 22 may include an organic material, a photoresist, or amorphous silicon. The first sacrificial patterns 22 may be formed using a patterning process.

When the first sacrificial patterns 22 are formed, the first gate insulating layer 11a may also be patterned so that the patterned first gate insulating layer 11a may have sidewalls aligned with sidewalls of the first sacrificial pattern 22. Grooves 24 may be formed between the first sacrificial patterns 22. In example embodiments, the source/drain region SD may be formed after the formation of the first sacrificial patterns 22. That is, the source/drain region SD may be formed in the substrate 10 exposed by the first sacrificial patterns 22. A capping layer 20 may be formed to conformally cover the first sacrificial patterns 22 and/or the substrate 10. The capping layer 20 may be in contact with the sidewalls of the first sacrificial patterns 22 and the sidewalls of the first gate insulating layer 11a and may extend onto the substrate 10 between the first sacrificial patterns 22.

Referring to FIG. 18, second sacrificial patterns 26 may be formed in the grooves 24 of FIG. 17, respectively. Top surfaces 26a of the second sacrificial patterns 26 may be closer to the substrate than top surfaces 22a of the first sacrificial patterns 22. The second sacrificial patterns 26 may be formed by a deposition process of an organic material and an etch-back process. A porous layer 25 may be conformally formed on the capping layer 20 and the second sacrificial patterns 26.

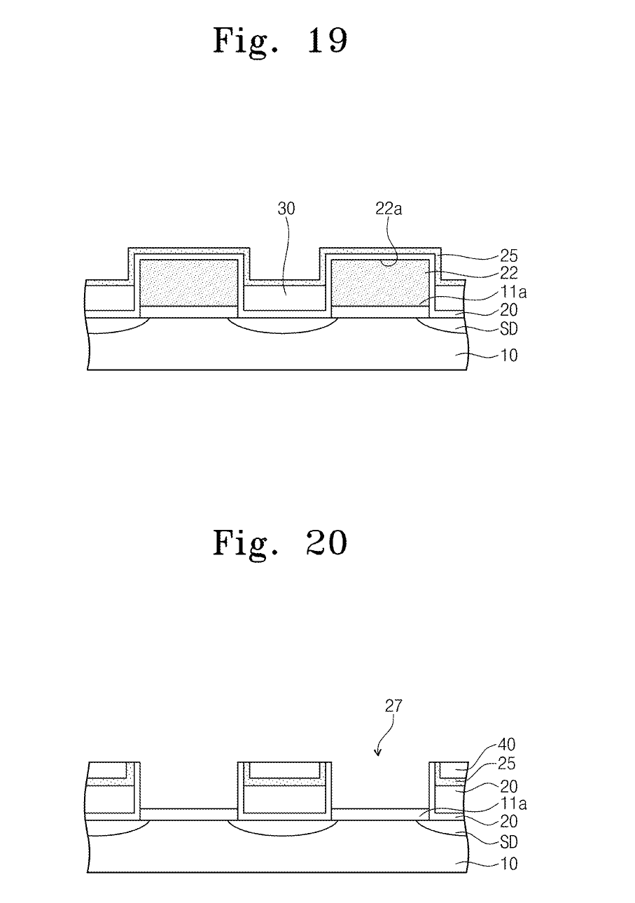

Referring to FIG. 19, the second sacrificial patterns 26 may be removed to form air gaps 30.

Referring to FIG. 20, a gap insulating layer 40 may be formed on the porous layer 25. The gap insulating layer 40 may cover the porous layer 25. The gap insulating layer 40 may be formed to be spaced apart from the substrate 10 and/or the capping layer 20. The capping layer 20, the porous layer 25, and the gap insulating layer 40 may be planarized to expose the first sacrificial patterns 22. The second sacrificial patterns 26, the porous layer 25, and the air gaps 30, and the gap insulating layer 40 may be formed by the same methods as described with reference to FIGS. 7 to 12. The first sacrificial patterns 26 may be removed to form trenches 27. The first sacrificial patterns 26 may be removed by an ashing process. The first gate insulating layer 11a may be exposed through the trench 27.

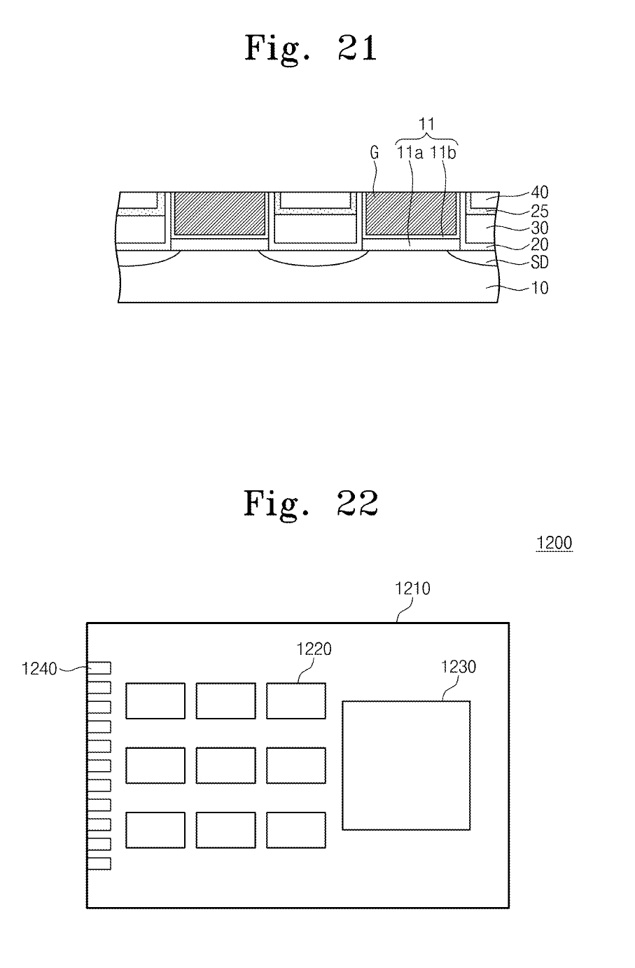

Referring to FIG. 21, a second gate insulating layer 11b may be formed in the trenches 27 of FIG. 20. The second gate insulating layer 11b may be provided on the first gate insulating layer 11a. In other embodiments, the second gate insulating layer 11b may extend along sidewalls of the trench 27. The second gate insulating layer 11b may include at least one of silicon nitride, silicon oxynitride, a metal silicate, and a relatively high melting point insulating metal oxide having a relatively high dielectric constant, for example, hafnium oxide and/or aluminum oxide. In other embodiments, the first gate insulating layer 11a may not be formed in the process described with reference to FIG. 17 but may be formed by thermally treating the substrate 10 exposed by the trenches 27 of FIG. 20. A gate insulating layer 11 includes the first gate insulating layer 11a and the second gate insulating layer 11b.

A gate electrode G may be formed on the gate insulating layer 11 in each of the trenches 27 of FIG. 20. The gate electrodes G may be formed on the gate insulating layer 11. The gate electrodes G may include a non-insulating material, for example, a conductive material, a metal, or a doped semiconductor. In example embodiments, a metal material (e.g., tungsten or aluminum) may be deposited to fill the trenches 27 of FIG. 20 and the deposited metal material may be planarized to form the gate electrodes G. In other embodiments, each of the gate electrodes G may include a metal nitride layer and a metal layer that are sequentially stacked.

[Applications]

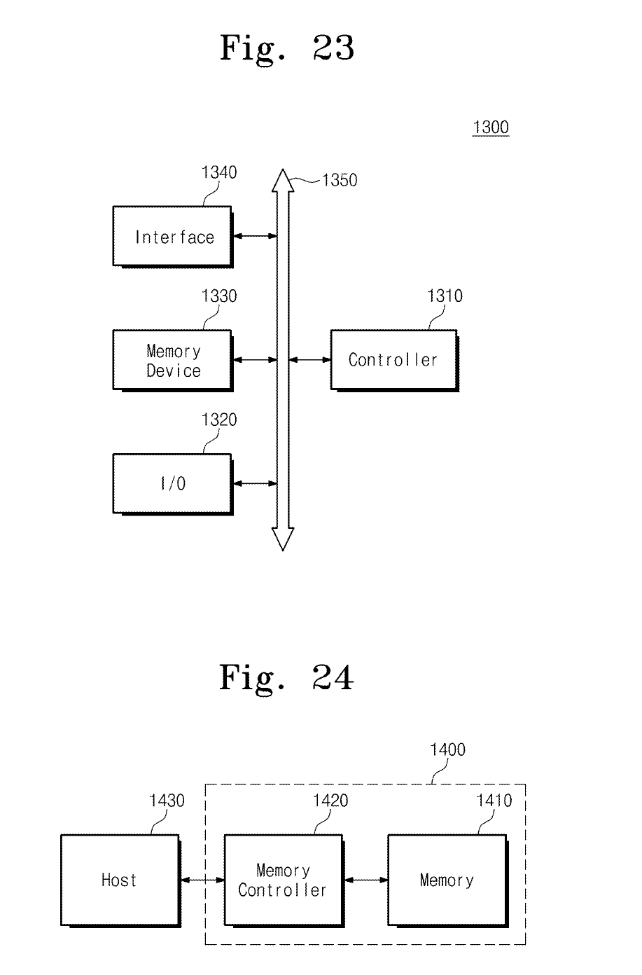

FIG. 22 illustrates an example of package modules including semiconductor devices according to various example embodiments of the inventive concepts. FIG. 23 is a schematic block diagram illustrating an example of electronic devices including semiconductor devices according to various example embodiments of the inventive concepts. FIG. 24 is a schematic block diagram illustrating an example of memory systems including semiconductor devices according to various example embodiments of the inventive concepts.

Referring to FIG. 22, a package module 1200 may include a semiconductor integrated circuit chips 1220 and a semiconductor integrated circuit chip 1230 packaged using a quad flat package (QFP) technique. The chips 1220 and 1230 may be mounted on a board 1210. The chips 1220 and 1230 may include at least one of the semiconductor devices 1 to 5 according to the aforementioned example embodiments of the inventive concepts. The package module 1200 may be connected to an external electronic device through external connection terminals 1240 provided on a side of the board 1210.

Referring to FIG. 23, an electronic device 1300 may include a controller 1310, an input/output (I/O) unit 1320 and a memory device 1330. The controller 1310, the I/O unit 1320 and the memory device 1330 may communicate with each other through a data bus 1350. The data bus 1350 may correspond to a path through which electrical signals are transmitted. For example, the controller 1310 may include at least one of a microprocessor, a digital signal processor, a microcontroller, or other logic devices having a similar function to any one of the microprocessor, the digital signal processor and the microcontroller. The controller 1310 and the memory device 1330 may include at least one of the semiconductor devices 1 to 5 according to the aforementioned example embodiments of the inventive concepts. The I/O unit 1320 may include a keypad, a keyboard and/or a display unit. The memory device 1330 may store data and/or commands executed by the controller 1310. The memory device 1330 may include a volatile memory device and/or a non-volatile memory device.

In example embodiments, the memory device 1330 may include a flash memory device. For example, the flash memory device applied with the technique according to the inventive concepts may be installed in an information processing system, e.g., a mobile device or a desk top computer. The flash memory device may be realized as solid state disks (SSD). In this case, the electronic device 1300 may stably store massive data in the memory device 1330. The electronic device 1300 may further include an interface unit 1340 that transmits electrical data to a communication network or receives electrical data from a communication network. The interface unit 1340 may operate by wireless or cable. For example, the interface unit 1340 may include an antenna for wireless communication or a transceiver for cable communication. Although not shown in the drawings, the electronic device 1300 may further include an application chipset and/or a camera image processor (CIS).

The electronic device 1300 may be realized as a mobile system, a personal computer, an industrial computer, or a multi-functional logic system. For example, the mobile system may be one of a personal digital assistant (PDA), a portable computer, a web tablet, a wireless phone, a mobile phone, a laptop computer, a digital music player, a memory card, or an information transmitting/receiving system. If the electronic device 1300 is an apparatus capable of performing a wireless communication, the electronic device 1300 may be used in a communication interface protocol, for example, a third generation communication system (e.g., CDMA, GSM, NADC, E-TDMA, WCDMA, CDMA2000).

Referring to FIG. 24, a memory system 1400 may include a non-volatile memory device 1410 and a memory controller 1420. The non-volatile memory device 1410 and the memory controller 1420 may store data or may read stored data. The non-volatile memory device 1420 may include at least one of the semiconductor devices 1 to 5 according to the aforementioned example embodiments of the inventive concepts. The memory controller 1420 may read data from/store data into the non-volatile memory device 1410 in response to read/write request of a host 1430.

According to example embodiments of the inventive concepts, the air gap may be formed between the conductive patterns by removing the second sacrificial pattern between the first sacrificial patterns. The air gap may extend into the recess region formed in the interlayer insulating layer. Because the semiconductor device according to the inventive concepts includes the air gap between the conductive patterns, the parasitic capacitance of the semiconductor device may be reduced to improve the operating speed of the semiconductor device.

While the inventive concepts has been described with reference to example embodiments, it will be apparent to those skilled in the art that various changes and modifications may be made without departing from the spirit and scope of the inventive concepts. Therefore, it should be understood that the above embodiments are not limiting, but illustrative. Thus, the scope of the inventive concepts is to be determined by the broadest permissible interpretation of the following claims and their equivalents, and shall not be restricted or limited by the foregoing description.

1. A method of forming a semiconductor device, the method comprising:
forming first sacrificial patterns on a substrate, the first sacrificial patterns spaced apart from each other;
forming a capping layer on the first sacrificial patterns;
forming a gap insulating layer spaced apart from a lower portion of the capping layer between the first sacrificial patterns in a vertical direction;
planarizing the gap insulating layer and the capping layer to expose the first sacrificial patterns;
removing the first sacrificial patterns to form trenches; and
forming conductive patterns in the trenches, the conductive patterns having an air gap therebetween and between the lower portion of the capping layer and the gap insulating layer.

2. The method of claim 1, further comprising:
forming a second sacrificial pattern on the capping layer between the first sacrificial patterns; and
forming a porous layer on the capping layer and the second sacrificial pattern.

3. The method of claim 2, further comprising:
removing the second sacrificial pattern through the porous layer to form the air gap between the conductive patterns and between the lower portion of the capping layer and the gap insulating layer.

4. The method of claim 2, wherein the forming a second sacrificial pattern forms the second sacrificial pattern to have a top surface closer to the substrate than top surfaces of the first sacrificial patterns.

5. The method of claim 1, wherein
the forming first sacrificial patterns includes defining a groove therebetween, and
the forming a gap insulating layer forms the gap insulating layer on an upper region of the groove such that the air gap is in a lower region of the groove.

6. The method of claim 1, further comprising:
forming an interlayer insulating layer on the substrate,
wherein the forming first sacrificial patterns forms the first sacrificial patterns on the interlayer insulating layer.

7. The method of claim 6, wherein the forming first sacrificial patterns further comprises:
etching the interlayer insulating layer to form a recess region in the interlayer insulating layer, the recess region being disposed under a space between the first sacrificial patterns.

8. The method of claim 7, wherein
the forming an interlayer insulating layer forms contacts connected to the conductive patterns, and
the air gap extends into the recess region between the contacts.

9. The method of claim 1, wherein the forming conductive patterns forms one of a metal and a doped semiconductor.

10. The method of claim 1, further comprising:
forming a source/drain region in the substrate exposed by the first sacrificial patterns; and
forming a gate insulating layer on the substrate.

11. The method of claim 9, wherein the forming conductive patterns forms one of tungsten and aluminum.

12. The method of claim 9, wherein the forming a gate insulating layer forms at least one of silicon oxide, a nitride, an oxynitride, a metal silicate, and an insulating metal oxide.

13-16. (canceled)

17. A method of forming a semiconductor device, the method comprising:
forming first sacrificial patterns on a substrate;
forming a capping layer on the first sacrificial patterns;
forming a second sacrificial pattern on the capping layer between the first sacrificial patterns;
forming a porous layer on the capping layer and the second sacrificial pattern;
removing the first sacrificial patterns to form trenches;
forming conductive patterns in the trenches; and
removing the second sacrificial pattern through the porous layer to form an air gap between the conductive patterns.

18. The method of claim 17, wherein the forming a second sacrificial pattern forms the second sacrificial pattern to have a top surface closer to the substrate than top surfaces of the first sacrificial patterns.

19. The method of claim 17, further comprising:
forming an interlayer insulating layer on the substrate,
wherein the forming first sacrificial patterns forms the first sacrificial patterns on the interlayer insulating layer.

20. The method of claim 19, wherein the forming first sacrificial patterns further comprises:
etching the interlayer insulating layer to form a recess region in the interlayer insulating layer, the recess region being disposed under a space between the first sacrificial patterns.

21. The method of claim 20, wherein
the forming an interlayer insulating layer forms contacts connected to the conductive patterns, and
the air gap extends into the recess region between the contacts.

22. The method of claim 17, wherein the forming conductive patterns forms one of a metal and a doped semiconductor.

23. The method of claim 17, further comprising:
forming a source/drain region in the substrate exposed by the first sacrificial patterns; and
forming a gate insulating layer on the substrate.

24. The method of claim 23, wherein the forming a gate insulating layer forms at least one of silicon oxide, a nitride, an oxynitride, a metal silicate, and an insulating metal oxide.
